(19) United States
(12) Patent Application Publication
(10) Pub. No.: US 2017/0049007 A1
(43) Pub. Date: Feb. 16, 2017

(54) MESHED COOLING STRUCTURE AND COOLING DEVICE HAVING THE SAME

(71) Applicant: High Power Lighting Corp., New Taipei City (TW)

(72) Inventors: Chih-Hung WEI, New Taipei City (TW); Ming-Chang WU, New Taipei City (TW); Jian-Yang WU, New Taipei City (TW); Pu WEN, New Taipei City (TW); Chih-Yang HSU, New Taipei City (TW)

(21) Appl. No.: 14/981,908

(22) Filed: Dec. 29, 2015

(30) Foreign Application Priority Data
Aug. 11, 2015 (TW) 104126073

(51) Int. Cl. H05K 7/20; F28F 3/02

(52) U.S. Cl. CPC H05K 7/20409; F28F 3/022

(57) ABSTRACT

A meshed cooling structure includes a cooling mesh and a thermally conductive component. The cooling mesh includes a plurality of mesh layers. Each mesh layer includes a plurality of cooling wires which are interlaced, and each cooling wire of each mesh layer has a caliber different from one another. The thermally conductive component supports and transfers heat to the cooling mesh. The thermally conductive component includes a base and a plurality of supporting bodies spaced side by side. A supporting height is formed between one side of each supporting body and the other side opposite to the one side. The one side of each supporting body supports and in contact with the cooling mesh. The other side of each supporting body is connected to the base. Each cooling wire and each supporting body are opposite to each other obliquely.

### TECHNICAL FIELD

The disclosure relates to a cooling structure, more particularly to a meshed cooling structure and a cooling device having the cooling structure.

### BACKGROUND

The cooling structure may increase cooling area and improve cooling efficiency. However, the hot air for taking away the heat of the cooling mesh may not be discharged smoothly and this makes the cooling effects much worse.

The current cooling device comprises a cooling fan, a cooling mesh and a thermally conductive body. The top surface of the thermally conductive body is for carrying and contacting the cooling mesh while the other side contacts the heat source. Thereby, the heat from the heat source is transferred to the cooling mesh while the cooling fan blows the cooling mesh and the thermally conductive body.

This design may take away the heat of the cooling mesh. Nonetheless, the cooling mesh is too close to the thermally conductive body and the thermally conductive body is without an exhaust design. Hence, hot air with heat goes directly to the thermally conductive body and is blocked while it cannot flow towards lateral directions. The hot air is unable to discharge smoothly and the thermally conductive body continuously accumulates heat. This therefore makes the heat of the heat source unable to be dissipated and significantly undermines the cooling effects, which has long been criticized.

Thus, it is important to provide an improved design capable of solving the aforementioned problems.

### SUMMARY

The purpose of the disclosure is to provide a meshed cooling structure and a cooling device having the cooling structure capable of ensuring the smooth cooling processes and bringing the functions of the cooling mesh into full play, thereby having better cooling effects.

To fulfill the purpose, the disclosure provides a meshed cooling structure comprising a cooling mesh and a thermally conductive component. The cooling mesh comprises a plurality of mesh layers. Each mesh layer comprises a plurality of cooling wires which are interlaced, and each cooling wire of each mesh layer has a caliber different from one another. The thermally conductive component supports and transfers heat to the cooling mesh, wherein the thermally conductive component comprises a base and a plurality of supporting bodies spaced side by side. A supporting height is formed between one side of each supporting body and the other side opposite to the one side. The one side of each supporting body supports and in contact with the cooling mesh. The other side of each supporting body is connected to the base. Each cooling wire and each supporting body are opposite to each other obliquely, and the caliber of each cooling wire of each mesh layer tapers along a lateral direction from the other side of each supporting body.

The disclosure further provides a cooling device having a meshed cooling structure comprising a cooling structure and a fan illustrated below.

The cooling structure comprises a cooling mesh and a thermally conductive component. The cooling mesh comprises a plurality of mesh layers. Each mesh layer comprises a plurality of cooling wires which are interlaced, and each cooling wire of each mesh layer has a caliber different from one another. The thermally conductive component supports and transfers heat to the cooling mesh, wherein the thermally conductive component comprises a base and a plurality of supporting bodies spaced side by side. A supporting height is formed between one side of each supporting body and the other side opposite to the one side. The one side of each supporting body supports and in contact with the cooling mesh. The other side of each supporting body is connected to the base. Each cooling wire and each supporting body are opposite to each other obliquely, and the caliber of each cooling wire of each mesh layer tapers along a lateral direction from the other side of each supporting body.

The fan is set up corresponding to the cooling structure. The cooling mesh is located between the fan and the thermally conductive component while the fan faces the cooling mesh and blows towards the thermally conductive component.

Compared to prior art, the disclosure has following effects: the hot wind is able to flow smoothly and is discharged through the airflow channel, thereby ensuring smooth cooling processes. This brings the functions of the cooling mesh into full play and produces better cooling effects.

### BRIEF DESCRIPTION OF THE DRAWINGS

The disclosure will become more fully understood from the detailed description and the drawings given herein below for illustration only, and thus does not limit the disclosure, wherein:

FIG. 1 is an exploded view of a cooling structure according to the first embodiment of the disclosure;

FIG. 2 is a top view of FIG. 1 after the assembly;

FIG. 3 is a sectional view of the cooling structure according to the first embodiment of the disclosure;

FIG. 4 is a sectional view of the cooling structure according to the second embodiment of the disclosure;

FIG. 5 is a sectional view of the cooling structure according to the third embodiment of the disclosure;

FIG. 6 is a sectional view of the cooling structure according to the fourth embodiment of the disclosure;

FIG. 7 is a sectional view of the cooling device of the disclosure; and

FIG. 8 is a sectional view of the cooling device applying on a heat source according to the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

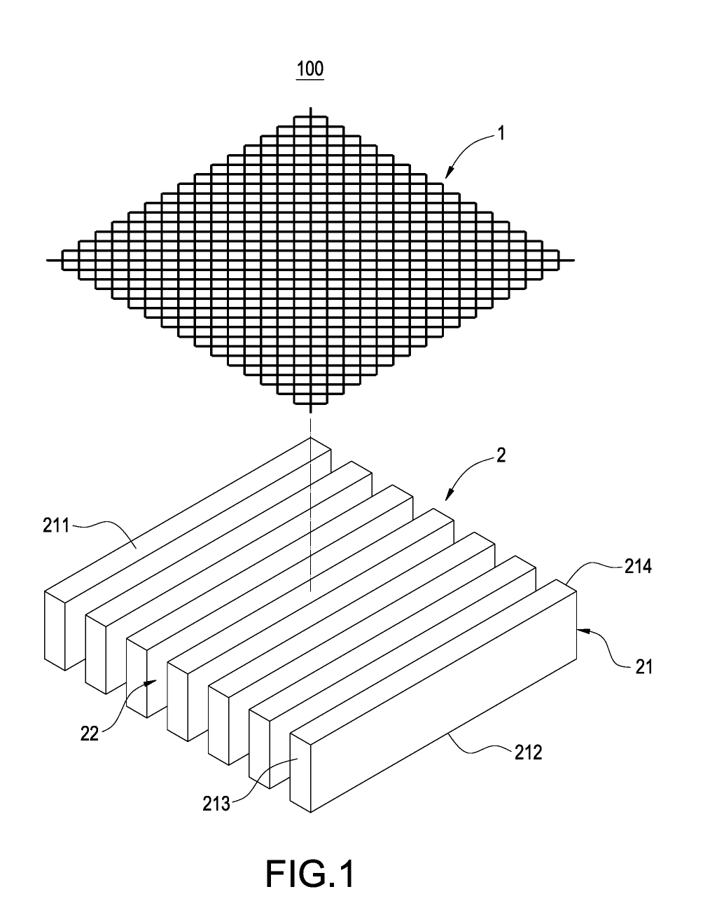

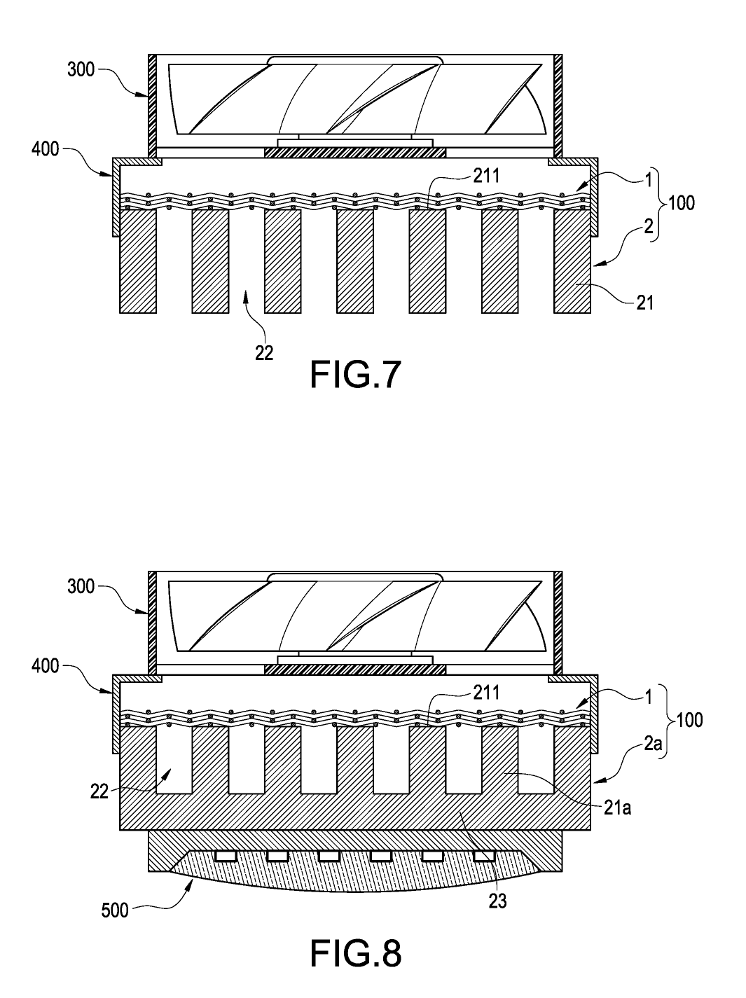

The disclosure provides a meshed cooling structure and a cooling device having the cooling structure. FIG. 1 to FIG. 6 show each embodiment of the cooling structure 100 of the disclosure. FIG. 7 and FIG. 8 show sectional views of the cooling device of the disclosure.

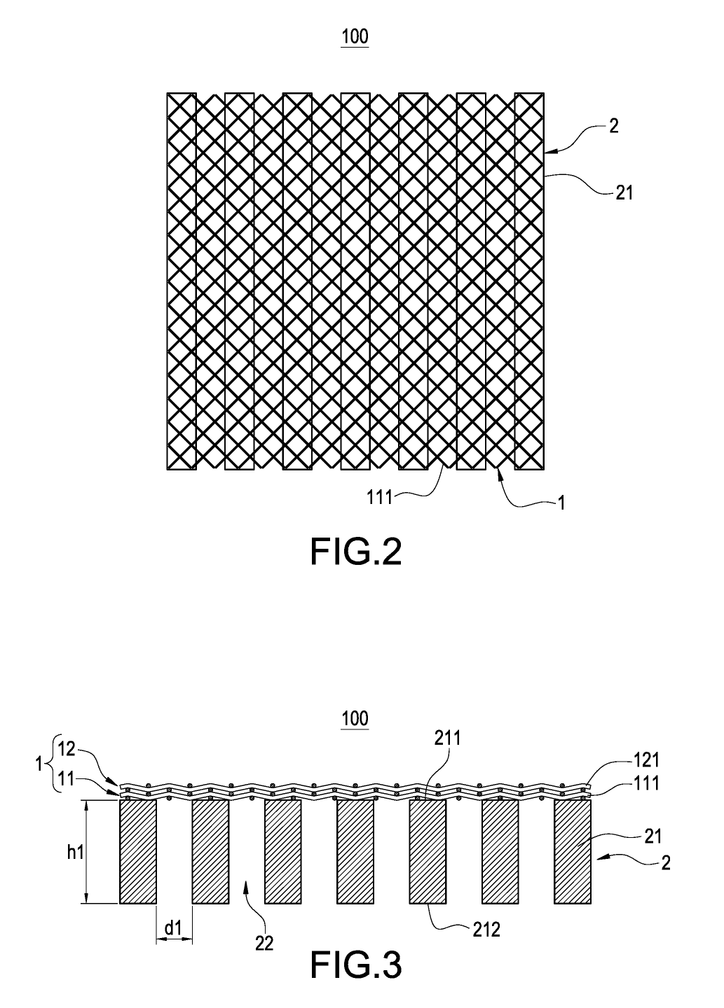

As seen in FIG. 1, FIG. 2 and FIG. 3, the cooling structure 100 of the first embodiment of the disclosure comprises a cooling mesh 1 and a thermally conductive component 2.

The cooling mesh 1 may be any kind of mesh, or may be a mesh having at least one mesh layer 11. In this embodiment, the cooling mesh 1 has two mesh layers 11 and 12, as an example for illustration. The mesh layers 11 and 12 comprise a plurality of cooling wires 111 and 121 interlaced, respectively. As seen in FIG. 3, the cooling wires 111 of the mesh layer 11 are interlaced so they overlap with each other while the cooling wires 121 of the mesh layer 12 are interlaced so they also overlap with each other.

The thermally conductive component 2 supports and transfer heat to the cooling mesh 1. The thermally conductive component 2 comprises a plurality of supporting bodies 21 spaced apart from each other. The supporting bodies 21 may be in any form while they are supporting walls (as seen in FIG. 1) in this embodiment, for example. Each supporting body 21 comprises a first side 211 and a second side 212 opposite to each other and a first end 213 and a second end 214 opposite to each other. The first end 213 and the second end 214 are connected between the first side 211 and the second side 212.

Specifically, a supporting height h1 is formed between the first side 211 and the second side 212 of each supporting body 21. The first side 211 of each supporting body 21 supports and contacts one side of the cooling mesh 1 such that each supporting body 21 transfers heat to the cooling mesh 1 via the first side 211.

Furthermore, each supporting body 21 is spaced side by side so a separating distance d1 is kept between any adjacent two supporting bodies 21. This way, an airflow channel 22 for hot air to flow is formed between any adjacent two supporting bodies 21. The positions of the airflow channel 22 corresponding to the first end 213 and the second end 214 are in open shapes to facilitate the hot air to be discharged into the outside.

Moreover, all the cooling wires 111 and 121 of the cooling mesh 1 are opposite to each supporting body 21 obliquely. That is, all the cooling wires 111 and 121 are arranged in manner not parallel to each supporting body 21 so no cooling wires 111 and 121 are not parallel to and do not contact any supporting body 21. This is because when one of the cooling wires 111 and 121 is not in contact with any supporting body 21, it would affect other cooling wires 111 or 121 which overlap with it, thereby affecting cooling effects negatively.

Consequently, air blown from the cooling mesh 1 towards the cooling component 2 takes away the heat of the cooling mesh 1 to become hot air. Each supporting body 21 has sufficient supporting height h1 and the separating distance d1 is kept between each supporting body 21 to form the airflow channel, so that the hot air flows smoothly in the airflow channel 22. This ensures smooth heat dissipation and produces better cooling effects.

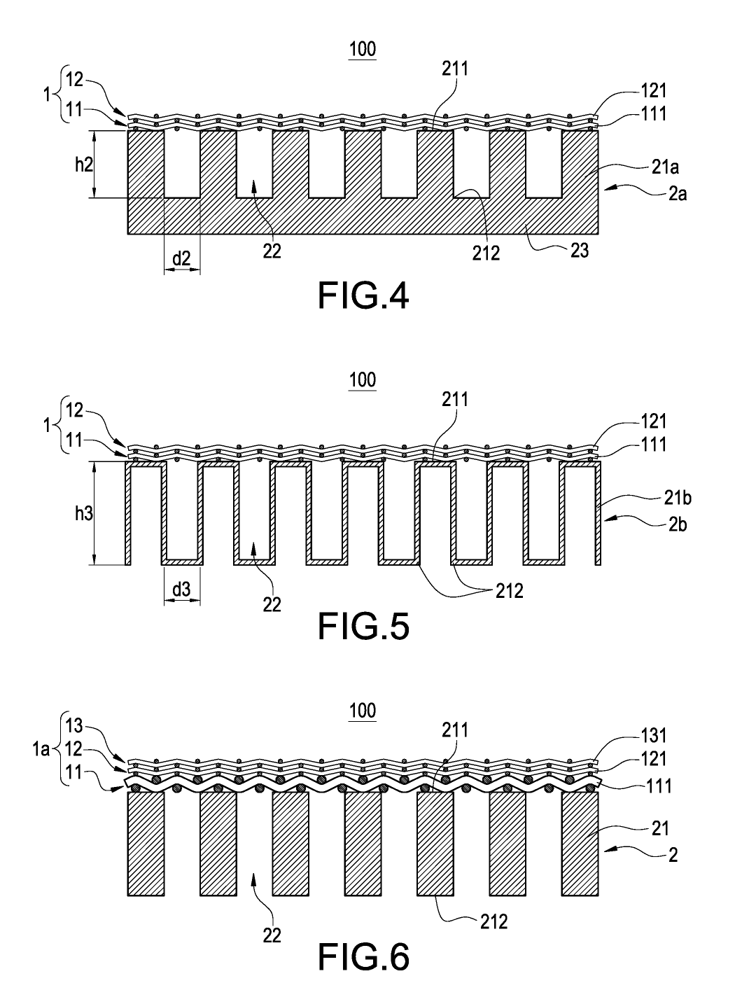

FIG. 4 shows the cooling structure 100 of the second embodiment of the disclosure. The second embodiment is similar to the first embodiment but the thermally conductive component 2a is different from the thermally conductive component 2 of the first embodiment. However, they both generate the same effect.

The thermally conductive component 2a further comprises a base 23. The second side 212 of each supporting body 21a is connected to the base 23 so each supporting body 21a has a supporting height h2 from the first side 211 to the second side 212. A separating distance d2 is kept between any adjacent supporting bodies 21a to form the airflow channel 22.

FIG. 5 shows the cooling structure 100 of the third embodiment of the disclosure. The third embodiment is similar to the first embodiment but the thermally conductive component 2b is different from the thermally conductive component 2 of the first embodiment. However, they both generate the same effect.

The thermally conductive component 2b is in a continuously bending shape that continuously bends towards the same direction, thereby forming each supporting body 21b by continuously bending. Each supporting body 21b has a supporting height h3 from the first side 211 to the second side 212. A separating distance d3 is kept between any adjacent supporting bodies 21b to form the airflow channel 22.

FIG. 6 shows the cooling structure 100 of the fourth embodiment of the disclosure. The fourth embodiment is similar to the first embodiment but the cooling mesh 1a is different from the cooling mesh 1 of the first embodiment. However, they both generate the same effect.

The cooling mesh 1a comprises a plurality of mesh layers 11, 12 and 13. The mesh layers 11, 12 and 13 of the cooling wires 111, 121 and 131 respectively have different calibers. In this embodiment, the calibers of the cooling wires 111, 121 and 131 taper (gradually decrease) towards a direction from the second side 212 to the first side 211 of the supporting body 21. As shown in FIG. 6, the cooling wire 111 next to the first side 211 is the thickest while the calibers of the other cooling wires 121 and 131 are identical and smaller than the caliber of the cooling wire 111.

FIG. 7 and FIG. 8 show a cooling device of the disclosure. The cooling device comprises the aforementioned cooling structure 100 and a fan 300, and preferably further comprises a wind guide shield 400.

In the situation not comprising the wind guide shield 400 (not shown in the figure), the fan is set up corresponding to the cooling structure 2 and 2a. For instance, the fan 300 is raised and screwed to the thermally conductive component 2 and 2a (not shown in the figure). This is merely one of the examples.

In the situation comprising the wind guide shield 400 (shown in FIG. 7 and FIG. 8), the wind guide shield 400 covers the cooling structure 100 while the fan 300 is set up on the wind guide shield 400. The cooling mesh 1 is located between the fan 300 and the thermally conductive component 2, 2a so that the fan 300 faces the cooling mesh 1 and blows the thermally conductive component 2, 2a. Due to the wind guide shield 400, the wind from the fan 300 is concentrated.

As seen in FIG. 8, when the second side 212 of the thermally conductive component 2 (not shown in the figures) or when the base 23 of the thermally conductive component 2a (shown in FIG. 8) contacts a heat source 500, the heat of the heat source 500 is transferred to the cooling mesh 1 via the thermally conductive component 2a to be taken away. When the fan 300 faces the cooling mesh 1 and blows the thermally conductive component 2a, the wind may take away the heat of the cooling mesh 1 to become hot wind.

At this point, a sufficient height, namely the supporting height h2 (as seen in FIG. 4), is maintained between the cooling mesh 1 and the base 23 of the thermally conductive component 2a. Additionally, the separating distance d2 is kept between any adjacent supporting bodies 21a to form the airflow channel 22 for ventilation. The hot wind may change direction from the direct direction blown towards the thermally conductive component 2a to the lateral direction towards the aforementioned two open ends of the airflow channel 22. Thus, the flow of the hot wind is smooth and not blocked, thereby discharging smoothly. The heat of the heat source 500 is dissipated effectively and this therefore improves the cooling effects.

To sum up, the disclosure compared to prior art includes the following effects: the hot wind flows smoothly and is discharged via the airflow channel 22, thereby ensuring the smooth cooling processes. This brings the cooling functions of the cooling mesh 1, 1a into full play, thereby performing better cooling effects.

Furthermore, the disclosure further includes the additional effect: the cooling wires 111, 121 and 131 are opposite to each supporting body 21, 21a and 21b obliquely so that no cooling wires 111, 121 and 131 of the cooling mesh 1 and 1a are not parallel to and do not contact any supporting body 21, 21a and 21b, thereby not affecting the cooling effects negatively

Moreover, the calibers of the cooling wires 111, 121 and 131 of each mesh layer 11, 12 and 13 tapers (gradually decrease) towards a direction from the second side 212 to the first side 211 of each supporting body 21, 21a and 21b, thereby improving the cooling effects.

The wind guide shield 400 may guide the wind from the fan 300 to concentrate and blow the cooling mesh 1 and 1a, thereby producing better cooling effects.

What is claimed is:

1. A meshed cooling structure, comprising:
a cooling mesh comprising a plurality of mesh layers, wherein each mesh layer comprises a plurality of cooling wires which are interlaced, each cooling wire of each mesh layer has a caliber different from one another; and
a thermally conductive component supporting and transferring heat to the cooling mesh, wherein the thermally conductive component comprises a base and a plurality of supporting bodies spaced side by side, a supporting height is formed between one side of each supporting body and the other side opposite to the one side, the one side of each supporting body supports and in contact with the cooling mesh, the other side of each supporting body is connected to the base, each cooling wire and each supporting body are opposite to each other obliquely, and the caliber of each cooling wire of each mesh layer tapers along a lateral direction from the other side of each supporting body.

2. The meshed cooling structure according to claim 1, wherein an airflow channel is formed between any adjacent two supporting bodies of the thermally conductive component.

3. The meshed cooling structure according to claim 2, wherein each supporting body has one end and the other end opposite to each other and connected between the one side and the other side, and the positions of the airflow channel corresponding to the one side and the other side are in open shapes to facilitate ventilation.

4. A cooling device having a meshed cooling structure, comprising:
a cooling structure, comprising:
a cooling mesh comprising a plurality of mesh layers, wherein each mesh layer comprises a plurality of cooling wires which are interlaced, each cooling wire of each mesh layer has a caliber different from one another; and
a thermally conductive component supporting and transferring heat to the cooling mesh, wherein the thermally conductive component comprises a base and a plurality of supporting bodies spaced side by side, a supporting height is formed between one side of each supporting body and the other side opposite to the one side, the one side of each supporting body supports and in contact with the cooling mesh, the other side of each supporting body is connected to the base, each cooling wire and each supporting body are opposite to each other obliquely, and the caliber of each cooling wire of each mesh layer tapers along a lateral direction from the other side of each supporting body; and
a fan set up corresponding to the cooling structure, the cooling mesh being located between the fan and the thermally conductive component while the fan facing the cooling mesh and blowing towards the thermally conductive component.

5. The cooling device having the meshed cooling structure according to claim 4, further comprising an wind guide shield disposed on the cooling structure, and the fan being set up on the wind guide shield.

6. The cooling device having the meshed cooling structure according to claim 4, wherein an airflow channel is formed between any adjacent two supporting bodies of the thermally conductive component.

7. The cooling device having the meshed cooling structure according to claim 6, wherein each supporting body has one end and the other end opposite to each other and connected between the one side and the other side, and the positions of the airflow channel corresponding to the one side and the other side are in open shapes to facilitate ventilation.
